(19) United States
(12) Patent Application Publication
(10) Pub. No.: US 2003/0156472 A1
(43) Pub. Date: Aug. 21, 2003

(54) Semiconductor integrated circuit device

(75) Inventors: Naofumi Satou, Chitose (JP); Kazutomo Ogura, Chitose (JP); Yutaka Ogawa, Chitose (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/244,002

(22) Filed: Sep. 16, 2002

(30) Foreign Application Priority Data
Feb. 15, 2002 (JP) 2002-037597

(51) Int. Cl. G11C 7/00

(52) U.S. Cl. 365/200

(57) ABSTRACT

There is provided a semiconductor integrated circuit device which can select the cache memory operation as required in which the priority is given to high speed operation or to low power consumption. In this circuit device, a set associative type cache memory includes read amplifier units for data-ways to provide a first operation mode for selecting an output from the data-way in relation to the cache hit state through the activation by giving limitation only to the read amplifier unit of the data-way in relation to the cache bit and a second operation mode for selecting an output from the data-way in relation to the cache hit without limitation on the read amplifiers to be activated. Selection of above operation mode is programmable depending on the setting of mode bit.

### BACKGROUND OF THE INVENTION

The present invention relates to a semiconductor integrated circuit wherein a set associative type cache memory is formed on a chip and particularly to a technique to assure high speed and low power consumption in the read operation under the cache hit condition which may be effectively applied, for example, to microcomputer, microprocessor, or data processor or the like.

An ordinary concept of a set associative type cache memory (set associative cache memory) will be explained briefly. The set associative cache memory includes an address unit and a data unit. The address unit stores cache tag information for associative comparison for every way. The data unit stores data information as cache entry for every way. The address unit is indexed with a part of the access address to reach the tag information. The tag information read out is compared with tag address of the relevant access address. When these addresses are matched, cache hit is defined and if these addresses are not matched, cache mistake is defined. When the cache hit is defined, the cache entry corresponding to the relevant access address exists in the data-way in relation to the cache hit. When the cache mistake is defined, the cache entry corresponding to the relevant access address does not exit in the data unit. For example, when the cache hit is defined at the time of read access, read data from the data-way in relation to the cache hit is selected the entire part of this data or a par of this data is outputted to an external circuit. When the cache mistake is defined, an access is actually executed from the access address to supply the necessary data. In this case, cache fill and moreover cache entry are replaced.

### SUMMARY OF THE INVENTION

The inventors of the present invention have discussed power consumption and read operation speed of the associative read operation in the set associative cache memory. In order to improve the read operation speed, it is effective to execute, also in the data unit, the index operation of data-way in parallel to the index for the address unit. In this case, there are a couple of control methods for outputting data of the hit data-way to an external circuit. In the first method, a sense amplifier is operated only in the data-way hit in the address comparison. In the second method, the sense amplifier is operated in all data-ways and the data of way in relation to the cache hit is selected finally in the output way selection circuit.

However, this method, similar to the first method, where the sense amplifier is operated only in the hit way, is disadvantage for high speed operation because the sense amplifier is operation after a hit signal has reached. On the other hand, in the second method, the read operation may be executed at a high speed but quantity of power consumption becomes too large because the circuits before the output way selection circuit are operated in all ways. In the product design stage, it must be determined to employ any one of the specifications of the first and second methods depending on the concept that any one of the high speed operation and low power consumption should have the priority. However, the inventors of the present invention have found that a certain semiconductor integrated circuit such as a microcomputer having loaded a cache memory sets the priority to the high speed operation depending on the operation mode or has an operation mode having priority in the low power consumption and that the cache memory has been availably and selectively used from the same point of view.

An object of the present invention is to provide a semiconductor integrated circuit which may select, as required, any one of the high speed operation and low power consumption of the cache memory to give the priority.

The aforementioned and the other objects and the novel features of the present invention will become apparent from the present specification and the accompanying drawings.

The typical inventions disclosed in the prevent invention will be explained briefly below.

[1] The operation mode in which power consumption is controlled although operation speed is rather low and the operation mode in which high speed operation is realized although power consumption is rather high by operating a read amplifier such as a sense amplifier in all data-ways and then finally selecting the data of the output way with the output way selection circuit can be switched by operating the read amplifier such as the sense amplifier only in the hit data-way in the set associative cache memory and then selecting an output of the way in the downstream side of the read amplifier.

Therefore, the same semiconductor integrated circuit may be selectively operation in any mode of the low power consumption operation mode and high speed operation mode. Accordingly, a semiconductor integrated circuit maker can provide with one chip design a product which can select a couple of specifications depending on the requested specification. A user of the semiconductor integrated circuit can selectively use the cache memory from the similar point of view when the priority is set to the high speed operation or low power consumption depending on the operation mode.

[2] In more practical profile of the present invention, the set associative type cache memory has the first operation mode in which activation is executed with limitation only to a read amplifier of data-way in relation to the cache hit to select an output from the data-way in relation to the cache hit and the second operation mode in which an output from the data-way in relation to the cache hit is selected without any limitation on the read amplifier to be activated.

The first operation mode and second operation mode may be designated using a control register. It is preferable that the control register is disposed in an address space of the central processing unit using the cache memory.

In more practical profile of the present invention, an aligner which can alter the bit format by inputting the data of a plurality of bits outputted from a plurality of read amplifiers for every data-way and a read way selector for selecting the way of the putout data by inputting an output of the aligner of respective data-ways are provided to select an output of the data-way using the read way selector. For example, a logic circuit is provided for inputting, in this case, a read amplifier activation timing signal, a read way selector selection timing signal, a cache hit signal for every way, and a mode signal, and outputting a read amplifier activation control signal for every way and a way selection control signal of read way selector. When the first operation mode is instructed, the logic circuit sets, as the activation instruction level, the read amplifier activation control signal of the way in which the cache hit signal instructs the cache hit in response to the activation timing with the read amplifier activation timing signal and also sets, as the selection instruction level, the way selection control signal of the way in which the cache hit signal instructs the cache hit in response to the selection timing by the selection timing signal of the read way selector. When the second operation mode is instructed, the read amplifier activation control signal of all ways is set as the activation instruction level in response to the activation timing by the activation timing control signal of the read amplifier and the way selection control signal of the way in which the cache hit signal instructs the cache hit in response to the selection timing by the selection timing signal of the read way selector is set as the selection instruction level.

Each data-way explained above has, for example, a plurality of memory mats and each memory mat has a read amplifier. Respective read amplifiers amplify the storage information read on the common data line for a plurality of data lines.

[3] According to the other profile of the present invention, the set associative cache memory loaded on the same chip as the semiconductor integrated circuit to be operated on the basis of the clock synchronization has the first operation mode in which the read amplifier of the data unit is activated after the cache hit signal has reached the data unit and the second operation mode in which the read amplifier is activated before the cache hit signal does not yet reach the data unit. In the first operation mode, the read amplifier to be activated is selected with the cache hit signal and an output of the activated read amplifier is selected based on the cache hit signal. In the second operation mode, an output of the activated read amplifier is selected based on the cache hit signal without limitation of the read amplifier to be activated with the cache hit signal.

### BRIEF DESCRIPTION OF THE DRAWINGS

FIG. 1 is a block diagram illustrating in detail a set associative cache memory loaded on the same chip as the semiconductor integrated circuit of the present invention.

FIG. 2 is a block diagram illustrating the entire part of a microcomputer as an example of the semiconductor integrated circuit of the present invention.

FIG. 3 is a block diagram illustrating in detail a data unit.

FIG. 4 is a circuit diagram illustrating in detail an example of a write amplifier of memory mat, a memory array, a sense amplifier and a driver.

FIG. 5 is a circuit diagram illustrating in detail an aligner.

FIG. 6 is a circuit diagram illustrating in detail a selector and a latch circuit.

FIG. 7 is a logic circuit diagram illustrating in detail a mode switching logic unit.

FIG. 8 is a timing chart illustrating an operation timing in the read hit state in the first operation mode (low speed operation mode).

FIG. 9 is a timing chart illustrating an operation timing in the read hit state in the second operation mode.

### DETAILED DESCRIPTION OF THE PREFERRED EMBODIMENTS

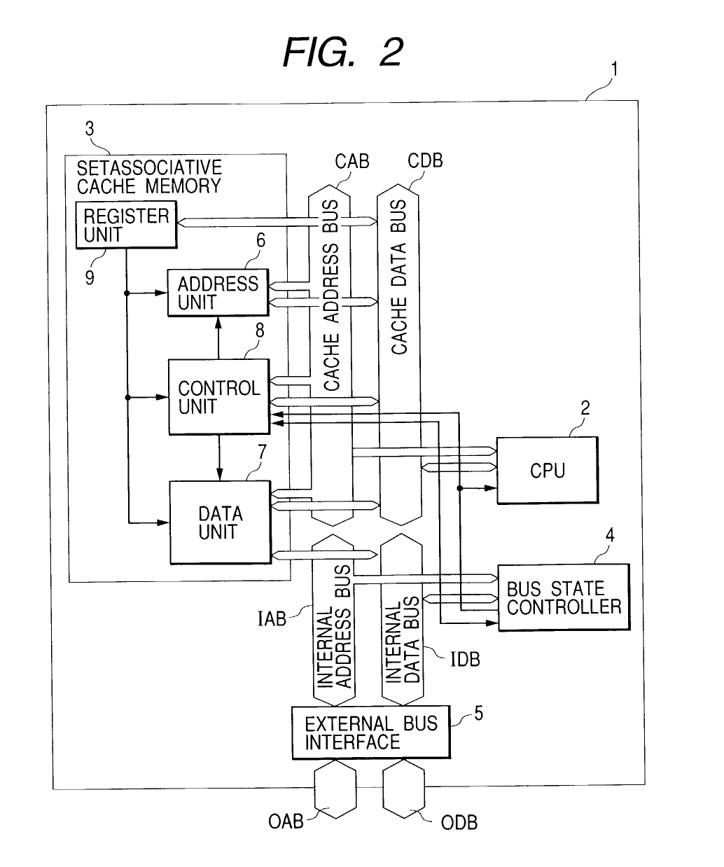

FIG. 2 illustrates the entire part of a microcomputer as an example of the semiconductor integrated circuit of the present invention. The microcomputer 1 illustrated in this figure is formed, for example, on one semiconductor substrate (semiconductor chip) like a single crystal silicon, for example, with CMOS integrated circuit manufacturing technique. On the semiconductor chip, circuit modules such as central processing unit (CPU) 2, set associative cache memory 3, bus state controller 4, and external bus interface 5 are formed. The set associative cache memory 3 includes an address unit 6, a data unit 7, a control unit (CCNT) 8, and a resister unit (CCR) 9. The cache address bus CAB and cache data bus CDB are connected to the address unit 6, data unit 7, control unit (CCNT) 8, and register unit (CCR) 9. The internal data bus IDB and internal address bus IAB are connected to the data unit 7, bus state controller 4 and external bus interface 5 or the like.

The CPU2 fetches an instruction and then decodes the instruction fetched to execute. The set associative cache memory 3 is used, although not particularly restricted, as an instruction cache and data cache. The bus state controller 4 controls, in response to the cache mistake of the cache memory 3, an external bus access by the external bus interface 5 via the external address bus OAB and external bus ODB or an internal bus access of the peripheral circuit module not illustrated and connected to the internal address bus IAB and internal data bus IDB.

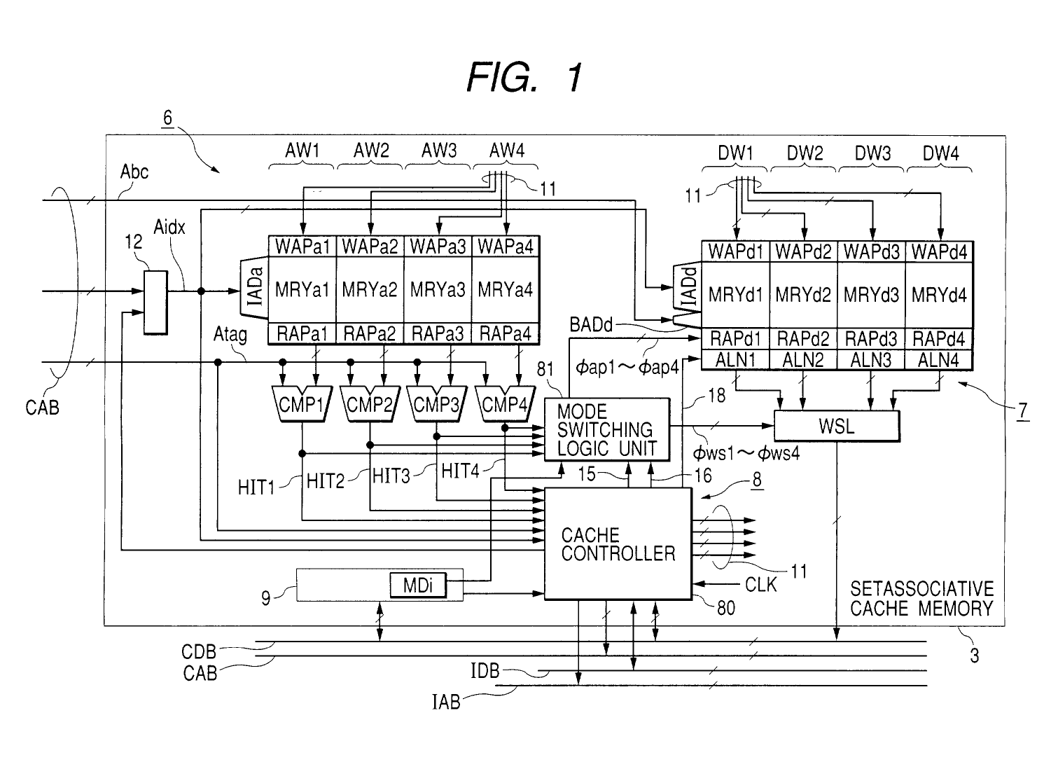

FIG. 1 illustrates in detail a set associative cache memory which is loaded on the same chip as the semiconductor integrated circuit of the present invention.

The set associative cache memory 3 is structured as a 4-way set associative cache memory having the four sets of way. The address unit 6 is provided with the address ways AW1 to AW4, while the data unit 7 is provided with the data-ways DW1 to DW4. The address ways AW1 to AW4 and data-ways DW1 to DW4 are structured, although not particularly restricted, by the memory block of SRAM (Static Random Access Memory).

The address ways AW1 to AW4 and data-ways DW1 to DW4 are indexed in common using a part of the addresses (index addresses Aidx) of the access address. The IADa, IADd are address decoders for index. The address ways AW1 to AW4 have the cache tag information or the like for every index address. The data-ways DW1 to DW4 store respectively the data information as the cache entry for every index address.

In FIG. 1, the respective address ways AW1 to AW4 have the typically illustrated memory arrays MRYa1 to MRYa4, read amplifiers RAPa1 to RAPa4, write amplifiers WAPa1 to WAPa4, and comparison circuits CMP1 to CMP4. The write amplifiers WAPa1 to WAPa4 amplify the write information such as tag information or the like supplied from the control unit 8 with the cache fill operation explained later and supplies the amplified tag information to the memory array. The read amplifiers RAPa1 to RAPa4 amplify the tag information or the like read from the memory arrays MRYa1 to MRYa4.

The address unit 6 inputs a part Aidx of the access address to an index decoder IADa for the purpose of index operation and reads the tag information from respective address ways AW1 to AW4. The tag information read out is compared with a tag address (Atag) of the relevant access address in the comparison circuits CMP1 to CMP4 and the comparison result is outputted as the cache hit signals HIT1 to HIT4. When these are matched, the cache hit is defined and when these are not matched, the cache mistake is defined. In the case of cache hit, the cache entry corresponding to the relevant access address exists in the data-way in relation to the cache hit. In the case of cache mistake, the cache entry corresponding to the relevant access address does not exit in the data unit.

The index operation by the index address Aidx is also conducted in the data unit 7 in parallel to the associative operation of the address unit 6. The cache entry (cache line) of each way indexed with the data-ways DW1 to DW4 can be extracted when a byte counter address decoder BADd receives a byte count address Abc of a plurality of least significant bits of the access address.

In FIG. 1, respective data-ways DW1 to DW4 have the typically illustrated memory arrays MRYd1 to MRYd4, read amplifiers RAPd1 to RAPd4, write amplifiers WAPd1 to WAPd4, and aligners ALN1 to ALN4. The write amplifiers WAPd1 to WAPd4 amplify the write data 11 supplied from the control unit 8 and supplies the amplified data to the memory arrays MRYd1 to MRYd4. The read amplifiers RAPd1 to RAPd4 amplify the stored information read from the memory arrays MRYd1 to MRYd4. The aligners ALN1 to ALN4 alter the bit arrangement of read data amplified by the read amplifiers RAPd1 to RAPd4 depending on the instruction of the control unit 8. Outputs of the aligners ALN1 to ALN4 are selected by a way selection circuit WSL and is then read to the external circuit. For example, at the time of read access, the read data from the data-way in relation to the cache hit is selected from the way selection circuit WSL and is then outputted to the external circuit in the case of cache hit. In the case of the cache mistake, the control unit 8 fetches the necessary data by making actual access to the access address and writes, for the cache fill, the fetched data to the memory arrays MRYd1 to MRYd4 of the data unit 7 and also writes the cache tag of the access address in this case to the memory arrays MRYa1 to MRYa4 of the address unit 6. In this case, when there is no vacant entry, the cache entry is replaced depending on the logic such as LRU (Least Recent Used). The address information required for cache fill operation is given to the address unit 6 and data unit 7 via a selector 12.

The control unit 8 has a cache controller 80 and a mode switching logic unit 81. The cache controller 80 inputs the cache hit signals HIT1 to HIT4, tag address Atag, index address Aidx, setting information of register unit 9 and clock signal CLK or the like to connect these to the address bus CAB, IAB and data bus CDB, IDB and to control the operation timing signal for the address unit 6 and data unit 7, cache fill in the cache mistake and replacement of cache entry.

The mode switching logic unit 81 controls the operating conditions of the read amplifiers RAPd1 to RAPd4 of the data unit 7 in the cache hit state. The register unit 9 has a mode bit (Mdi) to designate the first operation mode in which priority is given to the low power consumption even if the access speed is sacrificed in the cache hit (read hit) of the read access and the second operation mode in which priority is given to the high speed access. The mode switching logic unit 81 inputs the information of mode bit MDi, cache hit signals HIT1 to HIT4, activation timing signal 15 of the read amplifiers RAPd1 to RAPd4, and output selection timing signal 16 of the way selection circuit WSL. The mode switching logic unit 81 limits, when the first operation mode is designated with the mode bit MDi, the activation only to the read amplifier of the data-way in relation to the cache hit and selects an output of the data-way in relation to the cache hit with the way selection circuit WSL. When the second operation mode is designated, the mode switching logic unit 81 does not limit the activation only to the read amplifier and selects an output from the data-way in relation to the cache hit for the output of read amplifier with the way selection circuit WSL. The signals φap1 to φap4 are activation control signals of read amplifiers RAPd1 to RAPd4 for every data-way and the signals φws1 to φws4 are way selection control signals for the way selection circuit WSAL. The signal indicated as 18 is the 4-bit arrangement control signal by the aligners ALN1 to ALN4.

The mode switching explained above will be explained in further detail.

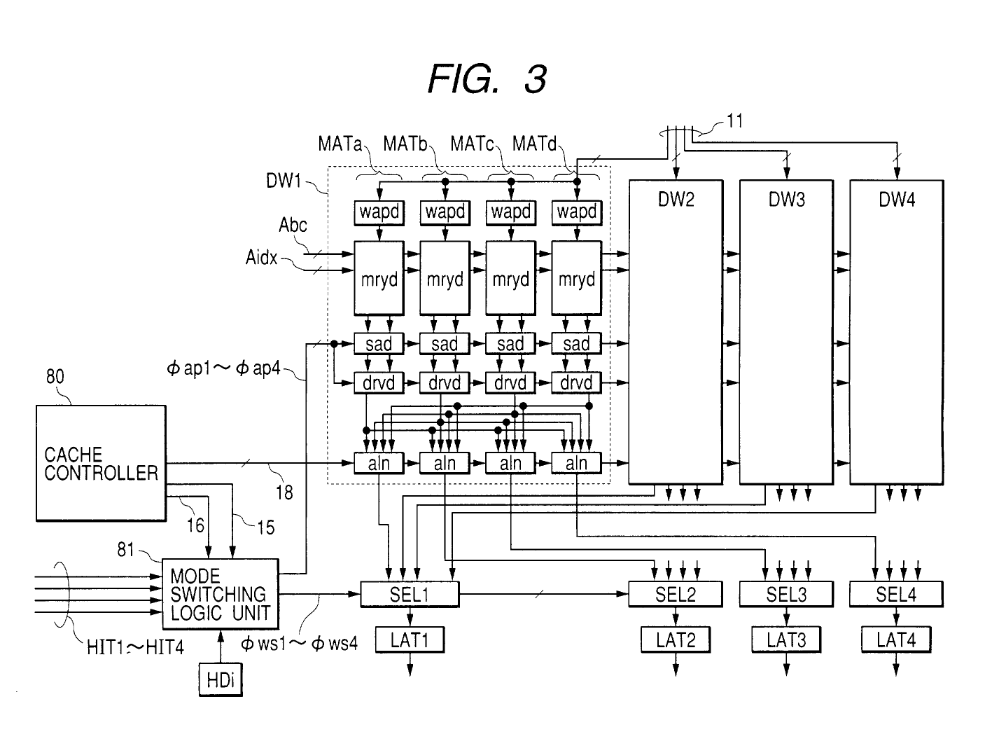

FIG. 3 illustrates details of the data unit. On way is divided, for example, into four memory mats MATa to MATd and each memory mat is provided with a write amplifier wapd, a memory array mryd, a sense amplifier sad, a driver drvd, and an aligner aln. Here, the sense amplifier sad and driver drvd form a read amplifier. Aggregation of the read amplifiers forms a read amplifier unit. According to FIG. 3, the four write amplifiers wapd in the mats MATa to MATd form a write amplifier WAPd in the data-way DW1, four memory arrays mryd form a memory array MRYd1, four sense amplifiers sad and drivers drvd form the read amplifier unit RAPd1 and four aligners aln form the aligner unit ALN1. The other data-ways DW2 to DW4 are also formed in the same manner.

In FIG. 3, the way selection circuit WSL is formed of four selectors SEL1 to SEL4 and four latch circuits LAT1 to LAT4. The selectors SEL1 to SEL4 selects any one of the data-ways DW1 to DW4 in unit of the corresponding memory mats MATa to MATd. For example, the selector SEL1 selects any one of the data-ways DW1 to DW4 as an output of the memory mat MATa. In the same manner, the selectors SEL2, SEL3, SEL4 respectively determine to select any one of the data-ways DW1 to DW4 as an output of the memory mat MATb, MATc and MATd.

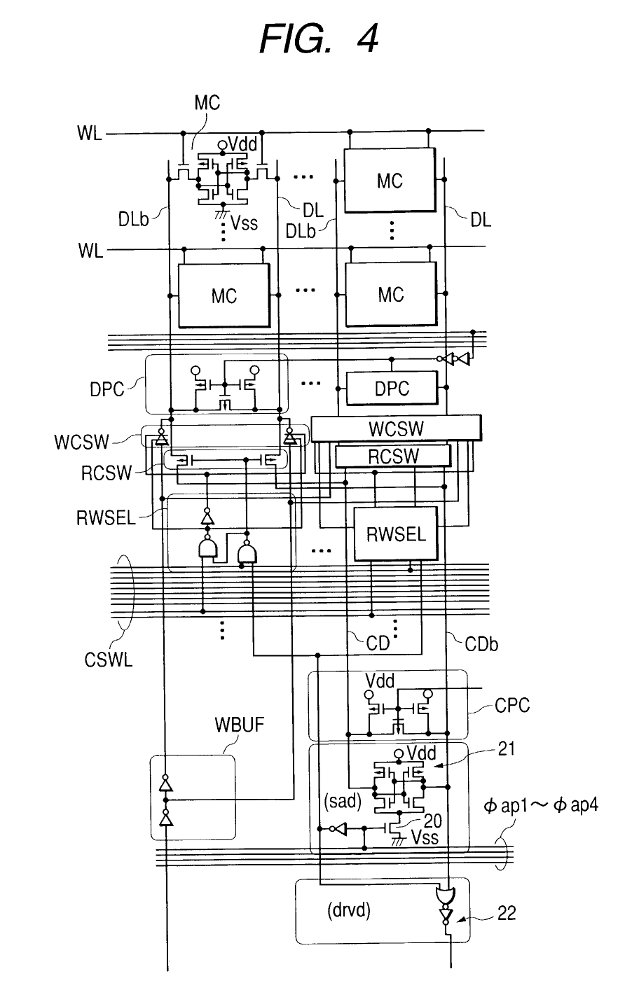

FIG. 4 illustrates a detail example of the write amplifier wapd, memory array mryd, sense amplifier sad and driver drvd of the memory mat. The memory array mryd is structured with a word line WL, static memory cells MCs, complementary data lines DL, DLb, a data line precharge circuit DPC, a read column switch RCSW, a write column switch WCSW, a column selection signal line CSWL, a read/write switching circuit RWSEL, complementary common data lines CD, CDb and a common data line precharge circuit CPC. The write amplifier wapd is structured by a write buffer WBUF. The sense amplifier sad is structured with a CMOS static latch 21 to which power source is selectively supplied with a power switch 20. The driver drvd is structured with a nor-inverter composite gate 22.

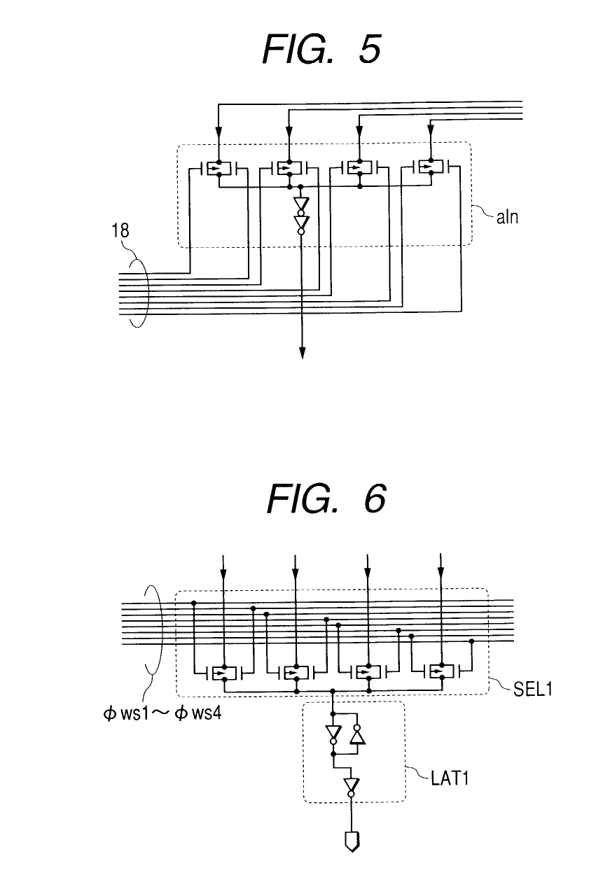

FIG. 5 illustrates the aligner aln in detail.

FIG. 6 illustrates in detail the selector SEL1 and latch circuit LAT1. The other selectors SEL2 to SEL4 and latch circuits LAT2 to LAT4 are also structured in the-same manner.

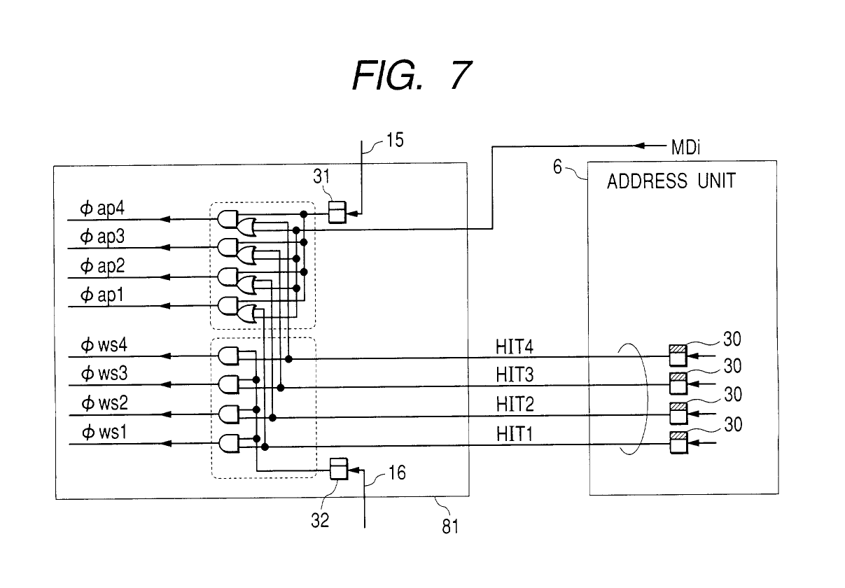

FIG. 7 illustrates in detail the mode switching logic unit 81. The logical value “0” of the mode bit MDi indicates the first operation mode in which priority is given to the low power consumption even if the access speed is sacrificed in the read hit state, while the logical value “1” of the mode bit MDi indicates the second operation mode in which priority is given to the high speed access. When the first operation mode is designated by the mode bit MDi, the activation control signals φapl to φap4 set, to the activation level, only the cache hit signals HIT1 to HIT4 corresponding to the read amplifier unit of the cache hit way in the activation timing of the read amplifier unit which is notified by the high level of activation timing signal 15. In the output selection timing of the way selection circuit WSL notified by the way output selection timing signal 16, the selection control signals φws1 to φws4 select the output from the data-way set to the cache hit state with the cache hit signals HIT1 to HIT4. On the other hand, when the second operation mode is designated with the mode bit MDi, in the activation timing of the read amplifier unit notified by high level of the activation timing signal 15, the activation control signals φapl to φap4 set the read amplifier units of all data-ways to the activation level without relation to the cache hit state by means of the cache hit signals HIT1 to HIT4. In the output selection timing of the way selection circuit WSL notified by the way output selection timing signal 16, the selection control signals φwa1 to φws4 select output from the data-ways set to the cache hit state with the cache hit signals HIT1 to HIT4.

The cache memory 3 is synchronously operated with the clock signal CLK as explained above. The latch circuit 30 is disposed in the transfer route of the bit signals HIT1 to HIT4 outputted from the comparison circuits CMP1 to CMP4, while the latch circuit 31 in the transfer route of the activation timing signal 15 of the read amplifier, 32 in the transfer route of the output way selection timing signal 16. The typical latch circuits 30, 31, 32 are latched synchronously with the clock signal CLK.

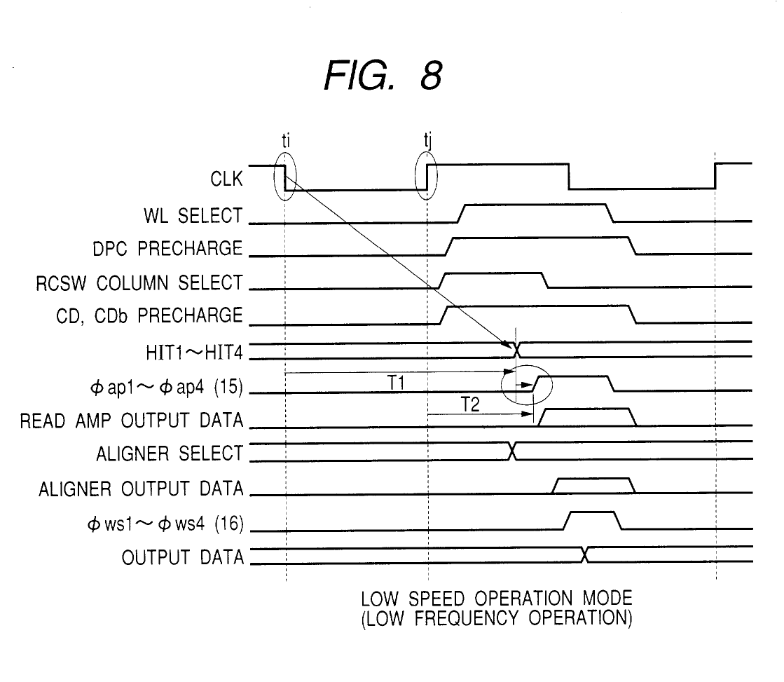

FIG. 8 illustrates the operation timings in the read hit state of the first operation mode (low speed operation mode). In the first operation mode, the frequency of clock signal CLK is set to a comparatively lower value. The time ti is defined as the output reference of the hit signal. For example, the latch circuit 30 of FIG. 7 latches the hit signals HIT1 to HIT4 synchronously with the falling edge of the clock signal CLK. The time tj is defined as the operation reference of the data arrays DW1 to DW4. The hit signals HIT to HIT4 transferred to the mode logic switching unit 81 are determined after the predetermined time T1 from the time ti. The activation timing signal 15 of the read amplifier unit is activated after the predetermined time T2 from the time tj. Here, the determination timing of the hit signals HIT1 to HIT4 is set matching with the activation of the activation timing signal 15 of the read amplifier unit. Accordingly, the activation object of the read amplifier unit can be limited only to the read amplifier unit of the data-way in relation to the hit state using the hit signals HIT1 to HIT4.

The time T2 may be adjusted by dividing the output side of latch circuit 31 to a plurality of routes of different transfer delay times and then selecting the divided route with a selector. Such adjustment may also be realized with the trimming at the manufacturing stage or with the setting of a mode register. For example, when manufacturing fluctuation is generated in the time T2 for the design value or when the activation timing of the read amplifier is not matched with determination of the hit signal because the time T2 is too long, such adjustment is effective.

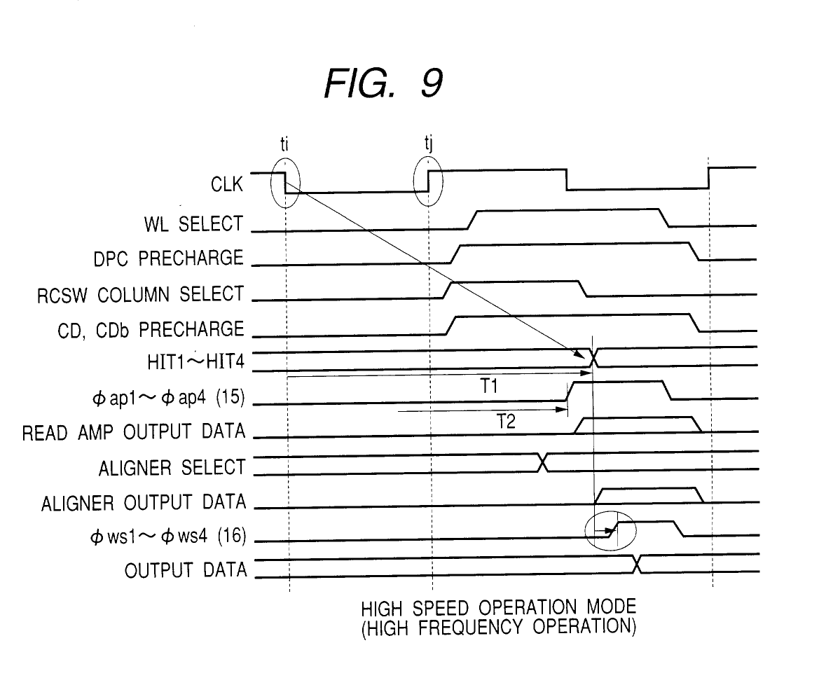

FIG. 9 illustrates the operation timings in the read hit state of the second operation mode (high speed operation mode). In the second operation mode, frequency of the clock signal CLK is set to a comparatively higher value. The hit signals HIT1 to HIT4 transferred to the mode logic switching unit 81 are determined after the predetermined time T1 from the time ti. The activation timing signal 15 of the read amplifier unit is activated after the predetermined time T2 from the time tj . Even when the frequency of clock signal CLK is different, the times T1, T2 are identical to that of FIG. 8 but since the period of clock signal CLK is rather short, the termination timing of the hit signals HIT1 to HIT4 is not matched with the activation of timing signal 15 of the read amplifier unit. Therefore, in the second operation mode, the activation object of the read amplifier is not limited to the data-way in relation to the hit state and the read amplifier unit is activated in all data-ways. The hit signals HIT1 to HIT4 are determined until the way selection operation by the way selection circuit WSL.

According to the microcomputer 1 explained above, one microcomputer 1 may selectively operated in any mode of the low power consumption operation mode or high speed operation mode. Therefore, a microcomputer maker can provide a product, only with one-chip design, which conforms to a couple of specifications for low power consumption and high speed operation. For users of microcomputer, it is possible, in the microcomputer in which a cache memory is loaded, to selectively use the cache memory 3 from the similar viewpoint in such a case that priority is given to the low power consumption.

The present invention has been explained practically on the basis of the preferred embodiment thereof. However, the present invention is not limited thereto and allows various changes and modification within the scope not departing from the claims thereof.

For example, the cache memory is not limited to the 4-way set and it is enough when the set associative cache memory has a plurality of ways. The number of memory mats of data-way is not limited to four. Each memory mat may be provided with a plurality of pairs of the common data line and sense amplifier. The read amplifier is not limited to a pair of the sense amplifier sad and driver drvd and the driver may also be eliminated when an output load of the sense amplifier is not so large. The cache memory is not limited to a unified cache in which both data and instruction are considered as the object of cache and any one of the instruction or data may be set as the object. Moreover, as the operation mode, a selective operation mode may also be provided in addition to the first and second operation modes. For example, the third operation mode for limiting the index operation of the data-way to data-way in relation to the cache hit state may be provided selectively. Further, the present invention is not limited to a microcomputer and can also be applied to a system LSI of the system-on-chip type which is designed in the logic system larger than such microcomputer. In addition, the present invention can also be adapted to a discrete cache memory.

The present invention can also provide the effects explained below.

Namely, the operation mode for giving priority to the low power consumption by operating a read amplifier such as a sense amplifier or the like only in the data-way which has been hit in the set associative cache memory and the operation mode for giving priority to the high speed operation by operating the read amplifier such as sense amplifier or the like in all data-ways may be switched. Thereby, a semiconductor maker is capable of providing a product, only with a one-chip-design method, which can select a couple of specifications of high speed operation and low power consumption conforming to the requested specifications. For the users of semiconductor integrated circuit, it is possible to selectively use the cache memory from the similar viewpoint when priority is given to the high speed operation and low power consumption depending on the operation mode in the semiconductor integrated circuit such as the microcomputer in which the cache memory is loaded.

What is claimed is:

1. A semiconductor integrated circuit device comprising:
a set associative type cache memory including a plurality of data-ways,
wherein said cache memory includes:
the first operation mode for selecting an output from a data-way in relation to the cache hit by activating a read amplifier of the data-way related to the cache hit with limitation thereto, and
the second operation mode for selecting an output from the data-way in relation to the cache hit without limitation of the read amplifier to be activated.

2. A semiconductor integrated circuit device according to claim 1, further comprising:
a control register having a setting area for control data designating said first operation mode or said second operation mode.

3. A semiconductor integrated circuit device according to claim 2, further comprising:
a central processing unit coupled to said cache memory and capable of accessing said control register.

4. A semiconductor integrated circuit device according to claim 1, further comprising:
an aligner which changes a bit arrangement of data having a plurality of bits outputted from a plurality of read amplifiers for every data-way, and
a read way selector for selecting a way of output data by inputting outputs of the aligners of respective data-ways,
wherein an output of the data-way is selected using said read way selector.

5. A semiconductor integrated circuit device according to claim 4, further comprising:
a logic circuit which inputs a read amplifier activation timing signal, a read way selector selection timing signal, a cache hit signal for every way, and a mode signal, and which outputs a read amplifier activation control signal for every way and a read way selector way selection control signal,
wherein said logic circuit sets, when the first operation mode is designated, to the activation designation level, the read amplifier control signal of the way in which the cache hit signal designates the cache hit in response to the activation timing by the activation timing signal of the read amplifier, and also sets, to the selection designation level, the way selection control signal of the way in which the cache hit signal designates the cache hit in response to the selection timing by the selection timing signal of the read way selector, and
wherein said logic circuits also sets, when the second operation mode is designated, to the activation designation level, the read amplifier activation control signal of all ways in response to the activation timing by the activation timing control signal of the read amplifier and sets, to the selection designation level, the way selection control signal of the way in which the cache hit signal designates the cache hit in response to the selection timing by the selection timing signal of the read way selector.

6. A semiconductor integrated circuit device comprising:
a central processing unit, and
a cache memory to synchronously operate with a clock signal,
said cache memory being a set associative type cache memory including a plurality of data-ways in the data unit, and
said cache memory having:
a first operation mode to activate a read amplifier of data unit after the cache hit signal has reached the data unit, and
a second operation mode for activating the read amplifier before the cache hit signal reaches the data unit.

7. A semiconductor integrated circuit device according to claim 6,
wherein said cache memory selects, in the first operation mode, the read amplifiers to be activated based on the cache hit signal and also selects outputs of the activated read amplifiers based on the cache hit signal, and
wherein said cache memory selects, in the second operation mode, outputs of the activated read amplifiers based on the cache hit signal without limitation on the read amplifiers to be activated by the cache hit signal.

8. A semiconductor integrated circuit device according to claim 7, further comprising:
a storage circuit which is accessed by said central processing unit,
wherein said storage circuit has an area for setting control data to designate said first operation mode or second operation mode.

9. A semiconductor integrated circuit device according to claim 8, further comprising:
a read way selector which inputs data outputted respectively from read amplifiers for every data-way and selectively output data of the predetermined way from the input data.

10. A semiconductor integrated circuit device according to claim 9, further comprising:
a logic circuit to input a read amplifier activation timing signal, a read way selector selection timing signal, a cache hit signal for every way, and a mode signal, and to output a read amplifier activation control signal for every way and a way selection control signal of said read way selector,
wherein said logic circuit sets, when the first operation mode is designated, to the activation designation level, the read amplifier activation control signal of the way in which the cache hit signal designates the cache hit in response to the activation timing by the activation timing signal of the read amplifier and also sets, to the selection designation level, the way selection control signal of the way in which the cache hit signal designates cache hit in response to the selection timing by the selection timing signal of said read way selector, and
wherein said logic circuit sets, when the second operation mode is designated, to the activation designation level, the read amplifier activation control signal of all ways in response to the activation timing by the activation timing control signal of the read amplifier and also sets, to the selection designation level, the way selection control signal of the way in which the cache hit signal designates cache hit in response to the selection timing by the selection timing signal of said read way selector.

11. A semiconductor integrated circuit device according to claim 1, wherein said each data-way includes a plurality of memory mats, each memory mat includes said read amplifiers, and respective read amplifiers amplify the stored information read on the common data line used for a plurality of data lines.

12. A semiconductor integrated circuit device according to claim 6, wherein said each data-way includes a plurality of memory mats, each memory mat includes said read amplifiers, and respective read amplifiers amplify the stored information read on the common data line used for a plurality of data lines.
